(19) United States
(12) Patent Application Publication
(10) Pub. No.: US 2010/0007252 A1
(43) Pub. Date: Jan. 14, 2010

(54) RACK SERVER CAPABLE OF DETACHING A REPLACEABLE MODULE CONVENIENTLY

(76) Inventor: Hung-Chun Liu, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/396,487

(22) Filed: Mar. 3, 2009

(30) Foreign Application Priority Data
Jul. 8, 2008 (TW) 097212088

(51) Int. Cl. A47B 81/00; H05K 7/00

(52) U.S. Cl. 312/223.2; 361/728

(57) ABSTRACT

A rack server includes a replaceable module, and a frame for supporting the replaceable module. Two slots are formed on both sides of the frame respectively. The rack server further includes a cover installed on the slots in a slidable manner. The cover includes a first housing and a second housing pivoted to the first housing. When the second housing rotates to a first position relative to the first housing, the second housing covers the replaceable module. When the second housing rotates to a second position relative to the first housing, the second housing can not cover the replaceable module. The rack server further includes a first fixing mechanism installed on a side of the slot of the frame for fixing the second housing on the frame when the second housing rotates to the first position relative to the first housing.

### BACKGROUND OF THE INVENTION

1. Field of the Invention

The present invention relates to a rack server, and more particularly, to a rack server capable of detaching a replaceable module conveniently.

2. Description of the Prior Art

In progress of computers and network, servers are utilized widely in common industry. A rack server has an advantage of small size so as to be arranged conveniently in a machine room. The rack servers are always piled up and neighboring with other servers, and the rack servers always operate for a long time. It is very important to dissipate heat generate by the rack server efficiently for stability and service life thereof. In general, fans are disposed inside the rack server to dissipate heat generated by internal components. However, maintenance workers have to draw out and get down the rack server from a shelf to take apart the rack server when replacing broken fans or upgrading instruments inside the rack server. It is also inconvenient for users to maintain or disassemble the conventional rack server.

### SUMMARY OF THE INVENTION

According to the claimed invention, a rack server includes a replaceable module, and a frame for supporting the replaceable module. Two slots are formed on both sides of the frame respectively. The rack server further includes a cover installed on the slots in a slidable manner. The cover includes a first housing and a second housing pivoted to the first housing. When the second housing rotates to a first position relative to the first housing, the second housing covers the replaceable module. When the second housing rotates to a second position relative to the first housing, the second housing can not cover the replaceable module. The rack server further includes a first fixing mechanism installed on a side of the slot of the frame for fixing the second housing on the frame when the second housing rotates to the first position relative to the first housing.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing of a rack server according to a preferred embodiment of the present invention.

FIG. 2 is an exploded diagram of the rack server according to the preferred embodiment of the present invention.

FIG. 3 is a diagram of a cover sliding on slots of a frame according to the embodiment of the present invention.

FIG. 4 is a diagram of a first fixing mechanism according to the preferred embodiment of the present invention.

FIG. 5 is an enlarged diagram of the first fixing mechanism combining with the frame according to the preferred embodiment of the present invention.

FIG. 6 is a diagram of a second housing of the cover rotating relative to a first housing so as to expose a thermal module according to the embodiment of the present invention.

FIG. 7 is a drawing of the cover according to the embodiment of the present invention.

FIG. 8 is an enlarged diagram of a second fixing mechanism combining with the frame according to the preferred embodiment of the present invention.

### DETAILED DESCRIPTION

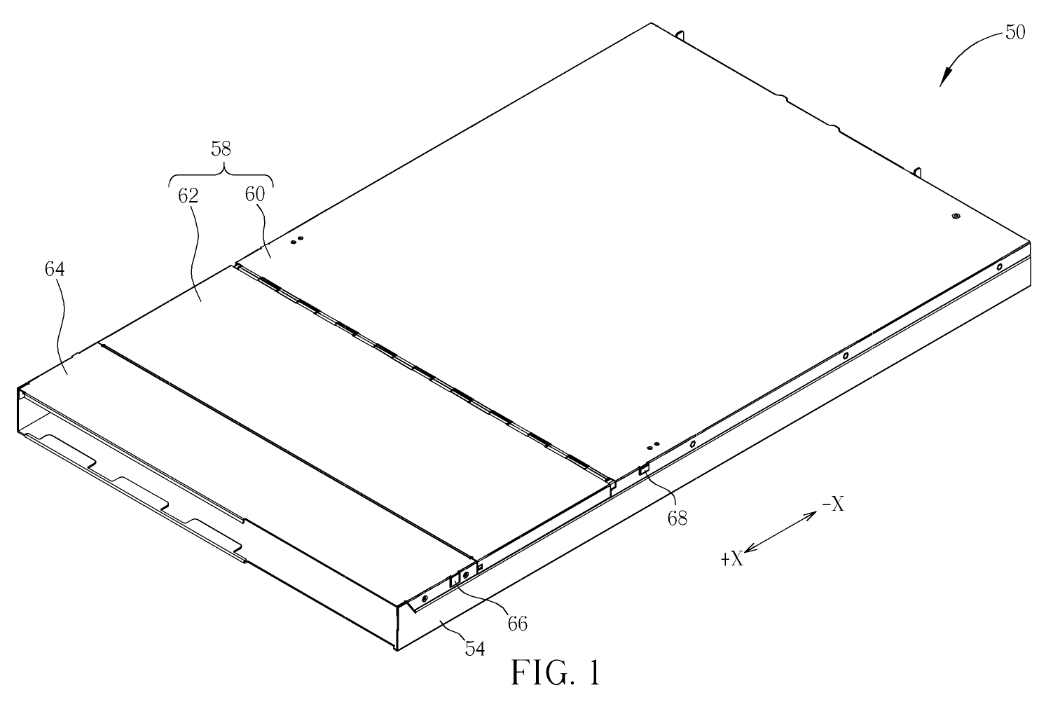

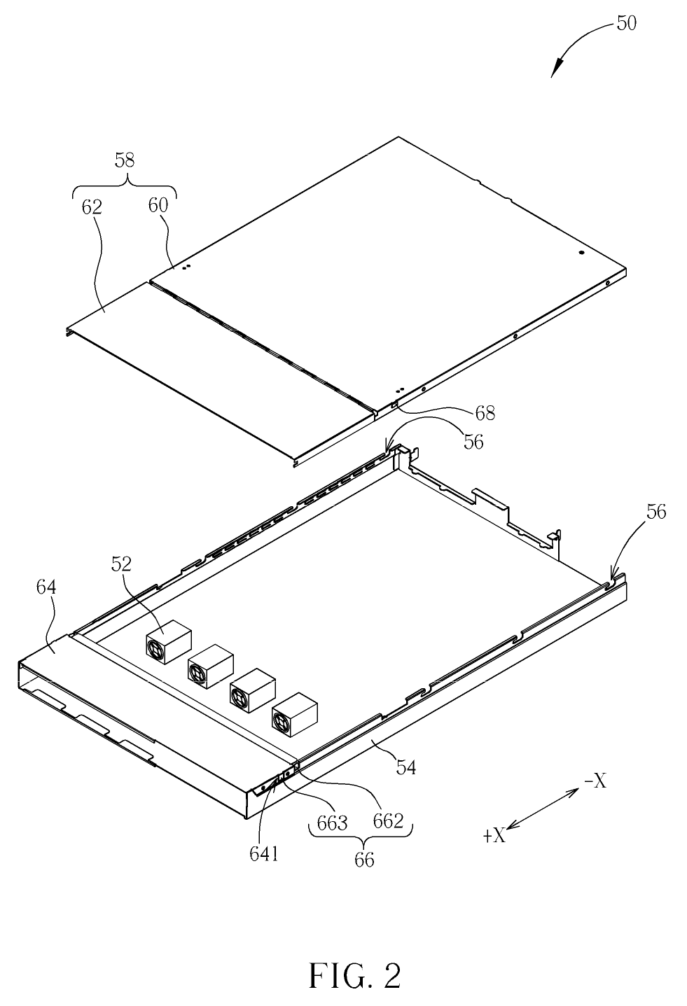

Please refer to FIG. 1 and FIG. 2. FIG. 1 is a schematic drawing of a rack server 50 according to a preferred embodiment of the present invention. FIG. 2 is an exploded diagram of the rack server 50 according to the preferred embodiment of the present invention. The rack server 50 includes at least one thermal module 52 for dissipating heat generated by internal components of the rack server 50. The thermal module 52 can be a fan. The rack server 50 further includes a frame 54 for supporting the thermal module 52 and internal components. Two slots 56 are formed on both sides of the frame 54 respectively. The rack server 50 further includes a cover 58 installed on the slots 56 of the frame 54 in a slidable manner. The cover 58 includes a first housing 60, and a second housing 62 pivoted to the first housing 60. The first housing 60 and the second housing 62 can be made of metal material so as to prevent electromagnetic interference (EMI) for the internal components. The rack server 50 further includes a fixing casing 64 fixed on the frame 54. The fixing casing 64 and the cover 58 cover the internal components supported by the frame 54 together. The fixing casing 64 also can be made of metal material so as to prevent electromagnetic interference for the internal components.

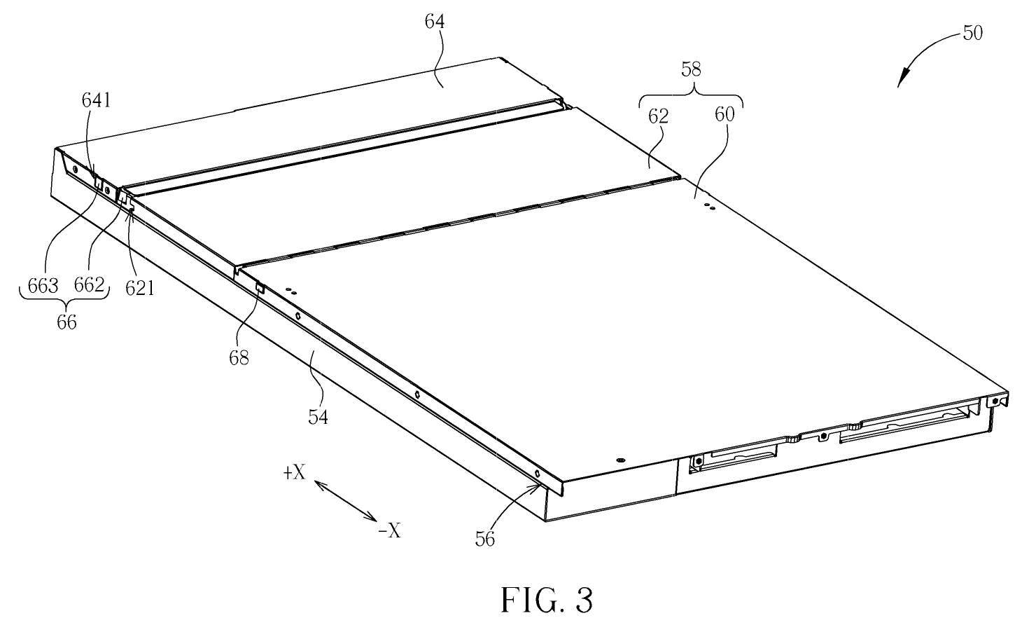

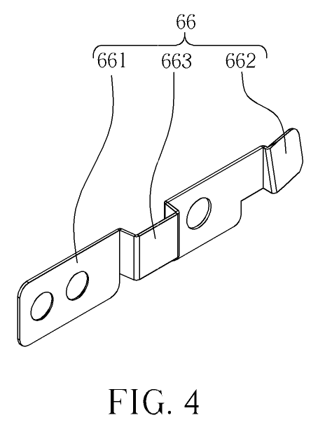

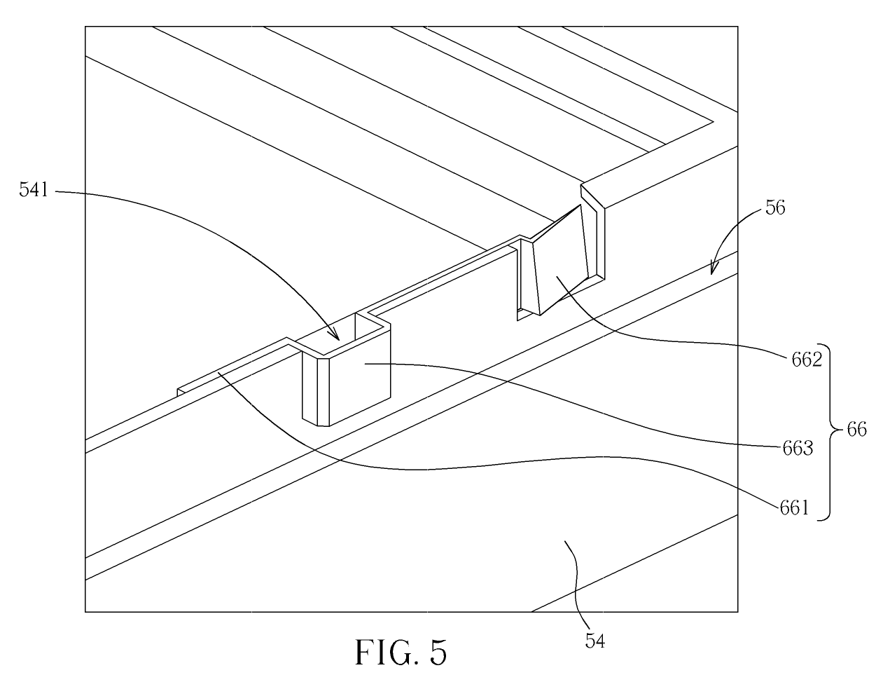

Please refer to FIG. 3. FIG. 3 is a diagram of the cover 58 sliding on the slots 56 of the frame 54 according to the embodiment of the present invention. The cover 58 is capable of sliding on the slots 56 of the frame 54 in +X or -X direction so as to install or disassemble the cover 58. The rack server 50 includes at least one first fixing mechanism 66 installed on a side of the slot 56 of the frame 54. Please refer to FIG. 4 and FIG. 5. FIG. 4 is a diagram of the first fixing mechanism 66 according to the preferred embodiment of the present invention. FIG. 5 is an enlarged diagram of the first fixing mechanism 66 combining with the frame 54 according to the preferred embodiment of the present invention. The first fixing mechanism 66 can be a fragment structure. The first fixing mechanism 66 includes a first connecting part 661 connected to an inner side of the frame 54, and a contacting part 662. An included angle is formed between the contacting part 662 and +X or −X direction that the cover 58 slides along the slots 56 on the frame 54 for guiding the cover 58 to slide on the slots 56 so that the cover 58 can not interfere with the contacting part 662 when the cover 58 slides along the slots 56 on the frame 54. The contacting part 662 can be made of elastic material. The first fixing mechanism 66 further includes a first driving part 663 connected to the first connecting part 661 and the contacting part 662. The first driving part 663 can be a bending component. A second opening 541 is formed on the frame 54, and the first driving part 663 protrudes out of the second opening 541 on the frame 54 so that the user can press the first driving part 663.

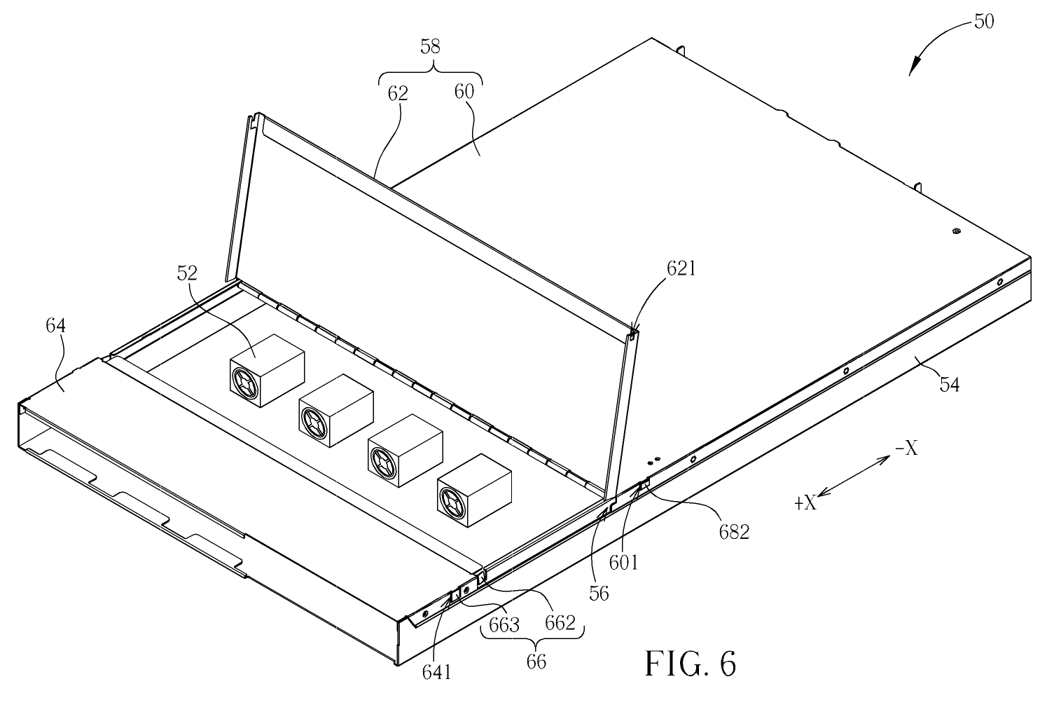

Please refer to FIG. 6. FIG. 6 is a diagram of the second housing 62 of the cover 58 rotating relative to the first housing 60 so as to expose the thermal module 52 according to the embodiment of the present invention. The second housing 62 is pivoted to the first housing 60. When the second housing 62 rotates relative to the first housing 60 to locate in a first position as shown in FIG. 1, the second housing 62 covers the thermal module 52 and the rack server 50 is under operation. A first opening 621 is formed on the second housing 62 of the cover 58. At this time, the contacting part 662 of the first fixing mechanism 66 contacts against the first opening 621 of the second housing 62 so as to fix the second housing 62 on the frame 54. A fourth opening 641 is formed on the fixing casing 64 and disposed in a position corresponding to the second opening 541 on the frame 54, and the first driving part 663 protrudes out of the second opening 541 on the frame 54 and the fourth opening 641 on the fixing casing 64 so that the user can press the first driving part 663. When the user wants to replace or disassemble the thermal module 52, the first driving part 663 needs to be pressed down first for releasing the constraint on the second housing 62 fixed on the frame 54 by the first fixing mechanism 66 so that the contacting part 662 can separate from the first opening 621 on the second housing 62. Then the second housing 62 can rotate to a second position as shown in FIG. 6 relative to the first housing 60, and the second housing 62 can not cover the thermal module 52 so that the user can take apart the thermal module 52.

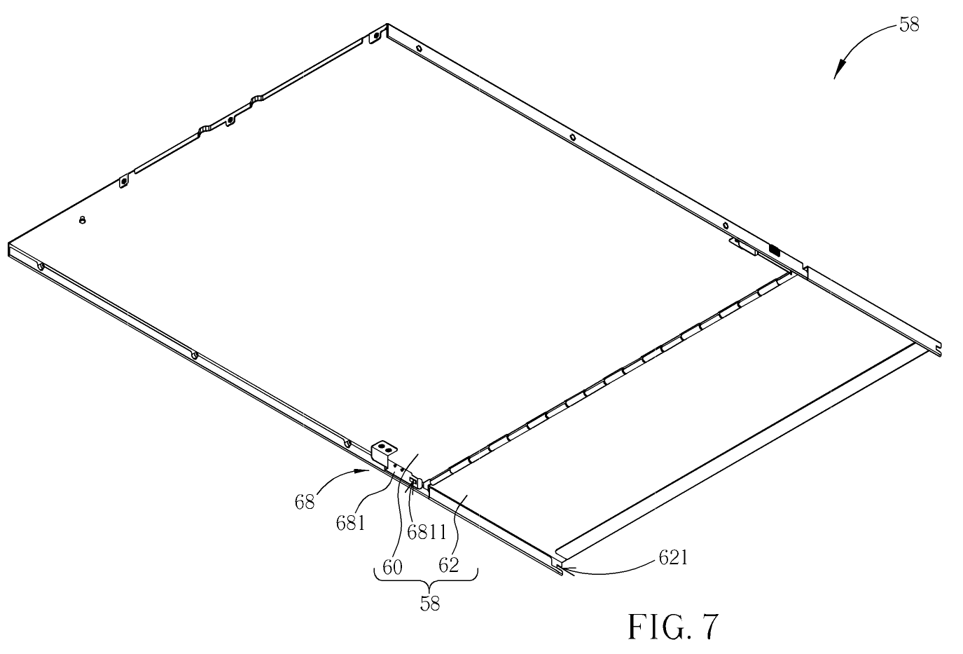

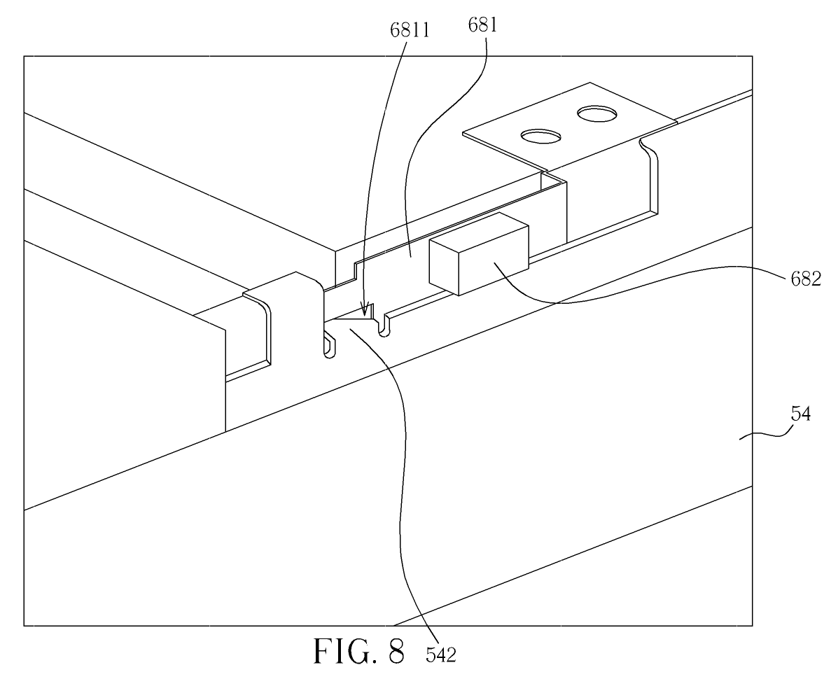

Please refer to FIG. 7. FIG. 7 is a drawing of the cover 58 according to the embodiment of the present invention. The rack server 50 further includes a second fixing mechanism 68 installed on an inner side of the first housing 60 for fixing the first housing 60 on the frame 54 when the cover 58 slides into the slots 56. Please refer to FIG. 8. FIG. 8 is an enlarged diagram of the second fixing mechanism 68 combining with the frame 54 according to the preferred embodiment of the present invention. A hook 542 is formed on the frame 54, and the second fixing mechanism 68 includes a second connecting part 681 connected to an inner side of the first housing 60. A hole 6811 is formed on the second connecting part 681 for wedging the hook 542 on the frame 54 so as to fix the first housing 60 on the frame 54. A third opening 601 is formed on the first housing 60. The second fixing mechanism 62 further includes a second driving part 682 connected to the second connecting part 681 and protruding out of the third opening 601. The second driving part 682 can be a protrusion, such as a button. The user can press down the second driving part 682 for driving the second connecting part 681 so as to separate the hook 542 from the hole 6811 on the second connecting part 681 for releasing the constraint on the first housing 60 fixed on the frame 54 by the second fixing mechanism 68. That is, after pressing down the second driving part 682 of the second fixing mechanism 68, the cover 58 is capable of sliding on the slots 56 on the frame 54 smoothly. The second fixing mechanism 68 is utilized for preventing the cover 58 from separating from the frame 54. In addition, the first opening 621, the second opening 541, the third opening 601, and the fourth opening 641 can be formed as other shapes for combining with fixing mechanisms correspondingly. The thermal module 52 can be substituted by other replaceable module. The mechanism of the present invention has an advantage of replacing internal components conveniently and easily.

In contrast to the prior art, the present invention provides a mechanism capable of replacing or detaching an internal component, such as a thermal module, conveniently and easily. There is no need to draw out and get down the rack server from a shelf when replacing or detaching the internal component of the rack server. The user only has to rotate the cover to open for uncovering the internal component so as to replace broken components or upgrading instruments inside the rack server conveniently and easily. In addition, the rack server is assembled without using screws so as to increase convenience of maintenance and assembly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A rack server comprising:
a replaceable module;
a frame for supporting the replaceable module, two slots being formed on both sides of the frame respectively;
a cover installed on the slots of the frame in a slidable manner, the cover comprising:
a first housing; and
a second housing pivoted to the first housing, the second housing covering the replaceable module when the second housing rotates to a first position relative to the first housing, and the second housing not covering the replaceable module when the second housing rotates to a second position relative to the first housing; and
a first fixing mechanism installed on a side of the slot of the frame for fixing the second housing on the frame when the second housing rotates to the first position relative to the first housing.

2. The rack server of claim 1 wherein the first fixing mechanism is a fragment structure.

3. The rack server of claim 2 wherein the first fixing mechanism comprising:
a first connecting part connected to an inner side of the frame;
a contacting part for contacting against a first opening on the second housing of the cover so as to fix the second housing in the first position; and
a first driving part connected to the first connecting part and the contacting part for driving the contacting part to separate from the first opening when being pressed down.

4. The rack server of claim 3 wherein a second opening is formed on the frame and the first driving part protrudes out of the second opening.

5. The rack server of claim 4 further comprising a fixing casing fixed on the frame, a fourth opening being formed on the fixing casing in a position corresponding to the second opening on the frame, and the first driving part protruding out of the second opening on the frame and the fourth opening on the fixing casing.

6. The rack server of claim 3 wherein the first driving part is a bending component.

7. The rack server of claim 3 wherein an included angle is formed between the contacting part and a direction of the cover sliding along the slot on the frame.

8. The rack server of claim 3 wherein the contacting part is made of elastic material.

9. The rack server of claim 1 further comprising a second fixing mechanism installed on the first housing for fixing the first housing on the frame when the cover slides into the slot.

10. The rack server of claim 9 wherein a hook is formed on the frame and the second fixing mechanism comprises:
a second connecting part connected to an inner side of the first housing, a hole being formed on the second connecting part for wedging the hook on the frame so as to fix the first housing on the frame; and
a second driving part connected to the second connecting part for driving the second connecting part so as to separate the hook from the hole on the second connecting part when being pressed down.

11. The rack server of claim 10 wherein a third opening is formed on the first housing and the second driving part protrudes out of the third opening.

12. The rack server of claim 10 wherein the second driving part is a protrusion.

13. The rack server of claim 1 further comprising a fixing casing fixed on the frame.

14. The rack server of claim 13 wherein the fixing casing is made of metal material.

15. The rack server of claim 1 wherein the replaceable module is a thermal module.

16. The rack server of claim 15 wherein the thermal module is a fan.

17. The rack server of claim 1 wherein the cover is made of metal material.
